(19) United States
(12) Patent Application Publication
(10) Pub. No.: US 2025/0369777 A1
(43) Pub. Date: Dec. 4, 2025

(54) DETECTION DEVICE

(71) Applicant: Japan Display Inc., Tokyo (JP)

(72) Inventor: Takayuki NAKANISHI, Tokyo (JP)

(21) Appl. No.: 19/213,709

(22) Filed: May 20, 2025

(30) Foreign Application Priority Data
May 30, 2024 (JP) 2024-088296

(51) Int. Cl. G01D 5/24

(52) U.S. Cl. CPC G01D 5/24

(57) ABSTRACT

According to an aspect, a detection device includes a detection region having a plurality of electrodes, and a detector configured to detect an object to be detected in proximity to the detection region based on a detection value of each of the electrodes. The detection region is divided into a plurality of functional regions. The detector is configured such that the functional regions have different modes for detecting the object to be detected.

### CROSS-REFERENCE TO RELATED APPLICATION

This application claims the benefit of priority from Japanese Patent Application No. 2024-088296 filed on May 30, 2024, the entire contents of which are incorporated herein by reference.

### BACKGROUND

### 1. Technical Field

What is disclosed herein relates to a detection device.

### 2. Description of the Related Art

In recent years, detection devices, what are called touch panels, capable of detecting external proximity objects have been used as user interfaces (UI) for controllers of household electrical appliances (hereinafter also referred to simply as “home appliances”) and displays of electronic apparatuses. WO 2019/082399 discloses a configuration in which the front surface of a touch sensor is provided with naturally derived wood, natural fiber, natural leather or a natural stone, or synthetic fiber, synthetic leather, an artificial stone or the like produced to imitate the natural appearance and feel.

In a configuration using what is called a capacitive touch panel as a UI for a controller of a home appliance or an electronic apparatus, it is necessary to perform processing corresponding to assigned functions. Specifically, for example, the determination threshold and the contents of processing at later stages differ depending on whether the assigned function is detecting an operation (gesture) corresponding to the movement of an object to be detected, such as the operator's finger, or detecting a touch operation on an operation button or the like printed on the surface of the controller of the home appliance or the electronic apparatus. A configuration provided with different components for the respective functions is not only disadvantageous in terms of cost but may possibly cause reduction in processing efficiency because a host individually receives the detection results from the components. The configuration needs to perform time-division operations to suppress interference of the detection operations performed by the respective components. As a result, the detection operation time for each of the functions decreases, which may possibly reduce the detection sensitivity.

For the foregoing reasons, there is a need for a detection device that can efficiently implement different functions in a plurality of regions on a single touch device.

### SUMMARY

According to an aspect, a detection device includes a detection region having a plurality of electrodes, and a detector configured to detect an object to be detected in proximity to the detection region based on a detection value of each of the electrodes. The detection region is divided into a plurality of functional regions. The detector is configured such that the functional regions have different modes for detecting the object to be detected.

### BRIEF DESCRIPTION OF THE DRAWINGS

FIG. 1 is a plan view of a schematic configuration of a detection device according to an embodiment;

FIG. 2 is a schematic of a sectional configuration of a sensor of the detection device according to the embodiment;

FIG. 3 is a schematic of an example of functional regions in a detection region;

FIG. 4 is a block diagram of an exemplary configuration of a detector of the detection device according to the embodiment;

FIG. 5 is a diagram of an example of the coupling configuration between the sensor and the detector of the detection device according to the embodiment;

FIG. 6A is a schematic of the relation between the position of an object to be detected in a space on a first functional region and the positions of respective electrodes;

FIG. 6B is a schematic of the spatial coordinates of the object to be detected in the space on the first functional region; and

FIG. 7 is a flowchart of an example of specific operations and processing performed by a processing circuit in the detection device according to the embodiment.

### DETAILED DESCRIPTION

Exemplary aspects (embodiments) to embody the present disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To make the explanation more specific, the drawings may possibly illustrate the width, the thickness, the shape, and other elements of each component more schematically than the actual aspect. These elements, however, are given by way of example only and are not intended to limit interpretation of the present disclosure. In the present specification and the drawings, components similar to those previously described with reference to previous drawings are denoted by the same reference numerals, and detailed explanation thereof may be omitted as appropriate.

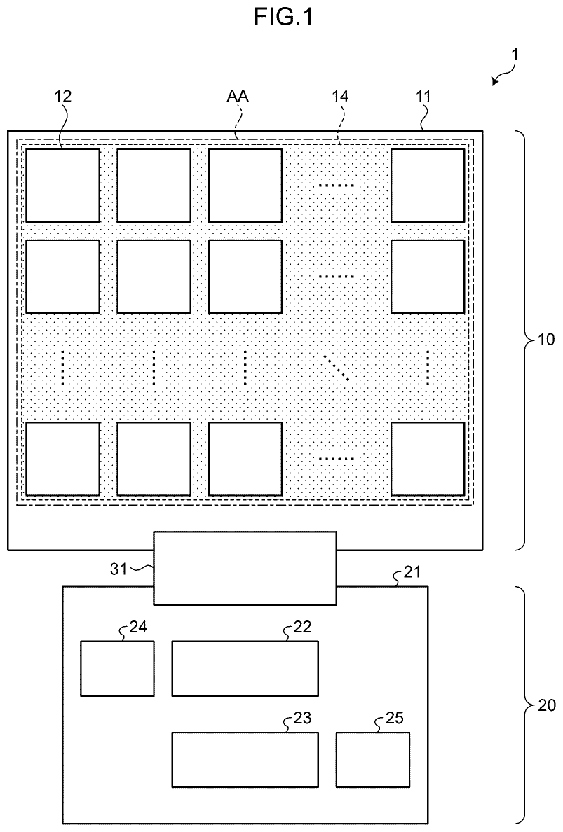

FIG. 1 is a plan view of a schematic configuration of a detection device according to an embodiment. A detection device 1 according to the present disclosure is used as a user interface (UI) for controllers of household electrical appliances (hereinafter also referred to simply as “home appliances”) or electronic apparatuses, for example. As illustrated in FIG. 1, the detection device 1 includes a sensor 10 and a detector 20.

The sensor 10 includes a sensor substrate 11 and a plurality of electrodes 12 provided in a detection region AA of the sensor substrate 11. The detector 20 acquires detection values corresponding to the capacitance generated in the electrodes 12 provided in the detection region AA to detect an object to be detected in proximity to the detection region AA. Specifically, the detector 20 includes a control substrate 21, a detection circuit 22, a processing circuit 23, a power supply circuit 24, and an interface circuit 25.

The detection region AA of the sensor substrate 11 is a region provided with the electrodes 12. The sensor substrate 11 is a rigid substrate or flexible printed circuits (FPC) with flexibility, for example. A shield electrode 14 is provided on the surface of the sensor substrate 11 opposite to the surface provided with the electrodes 12.

The sensor substrate 11 is electrically coupled to the control substrate 21 via a wiring substrate 31. The wiring substrate 31 is flexible printed circuits, for example. Each electrode 12 of the sensor 10 is coupled to the detection circuit 22 of the detector 20 via the wiring substrate 31.

The control substrate 21 is provided with the detection circuit 22, the processing circuit 23, the power supply circuit 24, and the interface circuit 25. The control substrate 21 is a rigid substrate, for example.

The detection circuit 22 generates a detection value of each electrode 12 based on a detection signal of the electrode 12 output from the sensor substrate 11. The detection circuit 22 is an analog front-end (AFE) IC, for example.

The processing circuit 23 detects an object to be detected (e.g., operator's finger) in the detection region AA or a space on the detection region AA based on the detection values of the respective electrodes 12 output from the detection circuit 22. The processing circuit 23 may be a programmable logic device (PLD), such as a field programmable gate array (FPGA), or a micro control unit (MCU), for example.

The power supply circuit 24 is a circuit that supplies power to the detection circuit 22 and the processing circuit 23.

The interface circuit 25 is a USB controller IC, for example, and is a circuit that controls communications between the processing circuit 23 and a host controller of a host device (not illustrated).

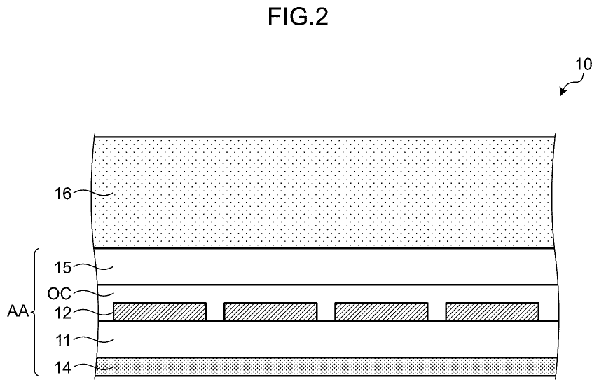

FIG. 2 is a schematic of a sectional configuration of the sensor of the detection device according to the embodiment. The sensor 10 includes the sensor substrate 11, the electrodes 12, the shield electrode 14, and an electrode protection layer 15.

The sensor 10 includes the electrode protection layer 15 facing one surface of the sensor substrate 11 on which a plurality of electrodes 12 are provided, with an adhesive layer OC interposed between the one surface of the sensor substrate 11 and the electrode protection layer 15. The shield electrode 14 is provided on the other surface of the sensor substrate 11. In the sensor 10, the layers of the shield electrode 14, the sensor substrate 11, the electrodes 12, and the electrode protection layer 15 are stacked in this order to form the detection region AA.

The surface layer of the electrode protection layer 15 according to the present disclosure is provided with an operation panel sheet 16 for a controller of a home appliance or an electronic apparatus, for example. In other words, the detection region AA of the sensor 10 is covered by the operation panel sheet 16.

The operation panel sheet 16 is a member made of non-conductive material. Specifically, examples of the material of the operation panel sheet 16 include, but are not limited to, naturally derived wood, natural fibers, and natural leather, or synthetic fibers and synthetic leather produced to imitate the natural appearance and feel, etc.

The detection region AA according to the present disclosure is divided into a plurality of functional regions having different modes for detecting the object to be detected. The following describes a specific example of how to divide the functional regions in the detection region AA and a mode for detecting the object to be detected for each of the functional regions.

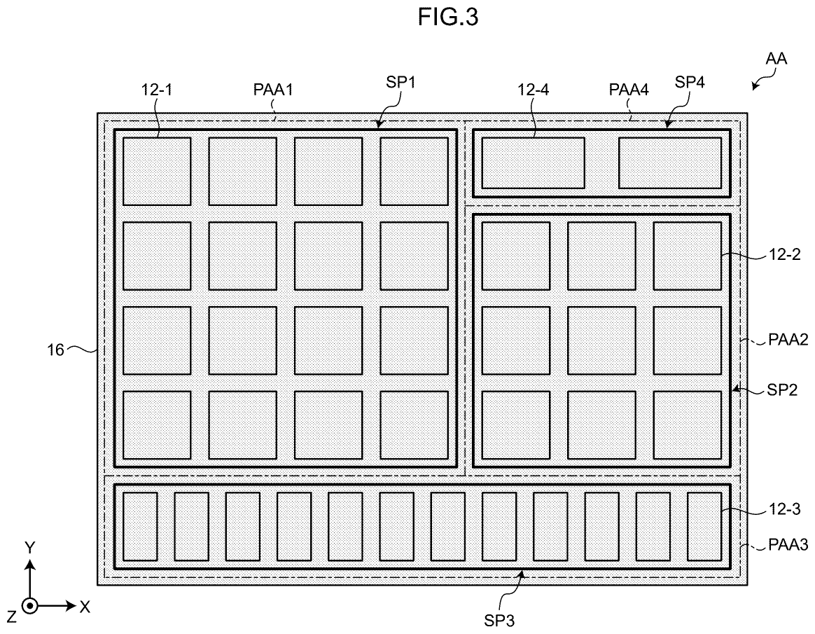

FIG. 3 is a schematic of an example of the functional regions in the detection region. In the example illustrated in FIG. 3, an X-direction and a Y-direction are orthogonal in the detection region AA. In the present disclosure, the direction orthogonal to the X-Y plane is referred to as a Z-direction. In the example illustrated in FIG. 3, the detection region AA is divided into a first functional region PAA1, a second functional region PAA2, a third functional region PAA3, and a fourth functional region PAA4.

FIG. 3 illustrates an example where the surface of the operation panel sheet 16 is provided with marks SP1, SP2, SP3, and SP4 that enable identifying the first functional region PAA1, the second functional region PAA2, the third functional region PAA3, and the fourth functional region PAA4, respectively. The marks SP1, SP2, SP3, and SP4 may be printed by silk-screen printing or marked by laser, for example.

In the example illustrated in FIG. 3, the first functional region PAA1 is a region where a plurality of electrodes are arranged in the X- and Y-directions. A plurality of electrodes 12-1 correspond to the electrodes 12 in FIGS. 1 and 2. In FIG. 3, the first functional region PAA1 is a region where four electrodes 12-1 are arranged in the X-direction and four electrodes 12-1 are arranged in the Y-direction, for example. The detector 20 detects the position of the object to be detected in the X-, Y-, and Z-directions in the space on the first functional region PAA1 based on the detection values of the electrodes 12-1 in the first functional region PAA1.

In the example illustrated in FIG. 3, the second functional region PAA2 is a region where a plurality of electrodes 12-2 are arranged in the X- and Y-directions. The electrodes 12-2 correspond to the electrodes 12 in FIGS. 1 and 2. In FIG. 3, the second functional region PAA2 is a region where three electrodes 12-2 are arranged in the X-direction and three electrodes 12-2 are arranged in the Y-direction, for example. The detector 20 detects the position of the object to be detected in the X- and Y-directions in the second functional region PAA2 based on the detection values of the electrodes 12-2 in the second functional region PAA2.

In the example illustrated in FIG. 3, the third functional region PAA3 is a region where a plurality of electrodes 12-3 are arranged in the X-direction. The electrodes 12-3 correspond to the electrodes 12 in FIGS. 1 and 2. In FIG. 3, the third functional region PAA3 is a region where 12 electrodes 12-3 are arranged in the X-direction, for example. The detector 20 detects the position of the object to be detected in the X-direction in the third functional region PAA3 based on the detection values of the electrodes 12-3 in the third functional region PAA3.

While the third functional region PAA3 is a region where a plurality of electrodes 12-3 are arranged in the X-direction in the example illustrated in FIG. 3, it may be a region where a plurality of electrodes 12-3 are arranged in the Y-direction. In this case, the detector 20 detects the position of the object to be detected in the Y-direction in the third functional region PAA3 based on the detection values of the electrodes 12-3 in the third functional region PAA3.

In the example illustrated in FIG. 3, the fourth functional region PAA4 is a region provided with at least one electrode 12-4. The electrode 12-4 corresponds to the electrode 12 in FIGS. 1 and 2. In FIG. 3, the fourth functional region PAA4 is a region provided with two electrodes 12-4, for example. The detector 20 detects the presence or absence of the object to be detected in the fourth functional region PAA4 based on the detection value of the electrode 12-4 in the fourth functional region PAA4.

While the detection region AA is divided into four functional regions of the first functional region PAA1, the second functional region PAA2, the third functional region PAA3, and the fourth functional region PAA4 in the example illustrated in FIG. 3, the functional regions in the detection region AA are not necessarily divided in this manner. Specifically, the detection region AA may include one first functional region PAA1 and one second functional region PAA2, for example. Alternatively, a plurality of the first functional regions PAA1, a plurality of the second functional regions PAA2, a plurality of the third functional regions PAA3, or a plurality of the fourth functional regions PAA4 may be provided. In the detection device 1 according to the present disclosure, the detection region AA simply needs to include at least one of the first functional region PAA1, the second functional region PAA2, the third functional region PAA3, and the fourth functional region PAA4, as a plurality of functional regions.

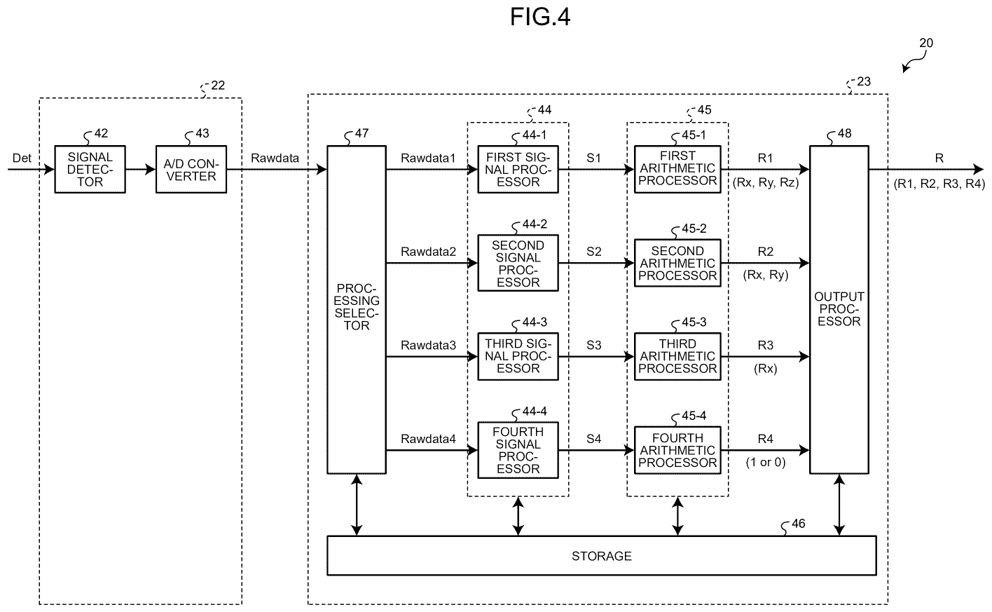

FIG. 4 is a block diagram of an exemplary configuration of the detector of the detection device according to the embodiment. FIG. 4 illustrates the configuration employed when the functional regions in the detection region AA are divided as in the example illustrated in FIG. 3. The following describes the aspect illustrated in FIG. 3 in which the detection region AA is divided into four functional regions of the first functional region PAA1, the second functional region PAA2, the third functional region PAA3, and the fourth functional region PAA4.

As illustrated in FIG. 4, the detector 20 includes a signal detector 42, an analog-to-digital (A/D) converter 43, a signal processor 44, an arithmetic processor 45, a storage 46, a processing selector 47, and an output processor 48. The signal detector 42 and the A/D converter 43 are included in the detection circuit 22. The signal processor 44, the arithmetic processor 45, the storage 46, the processing selector 47, and the output processor 48 are included in the processing circuit 23.

The storage 46 stores therein various parameters, tables, and the like used in the processing performed by the signal processor 44 and the arithmetic processor 45. The storage 46 also has a function of storing therein intermediate data and other data in the processing performed by the signal processor 44 and the arithmetic processor 45.

In the present disclosure, the correspondence between the electrodes 12 in the detection region AA and the functional regions is set in advance, and stored in the storage 46.

More specifically, in the example illustrated in FIG. 3, the storage 46 sets in advance the first functional region PAA1 where the electrodes 12-1 are arranged in the X- and Y-directions, the second functional region PAA2 where the electrodes 12-2 are arranged in the X- and Y-directions, the third functional region PAA3 where the electrodes 12-3 are arranged in the X-direction, and the fourth functional region PAA4 including the electrode 12-4.

The signal detector 42 generates a detection value Rawdata of each electrode 12 based on a detection signal Det of the electrode 12 output from the sensor substrate 11. The A/D converter 43 samples the detection value of each electrode 12 and converts it into a digital signal.

The signal processor 44 performs various processes, such as baseline processing and linear transformation, on the detection value Rawdata of each electrode 12 and outputs the processing result as a detection value S of the electrode 12.

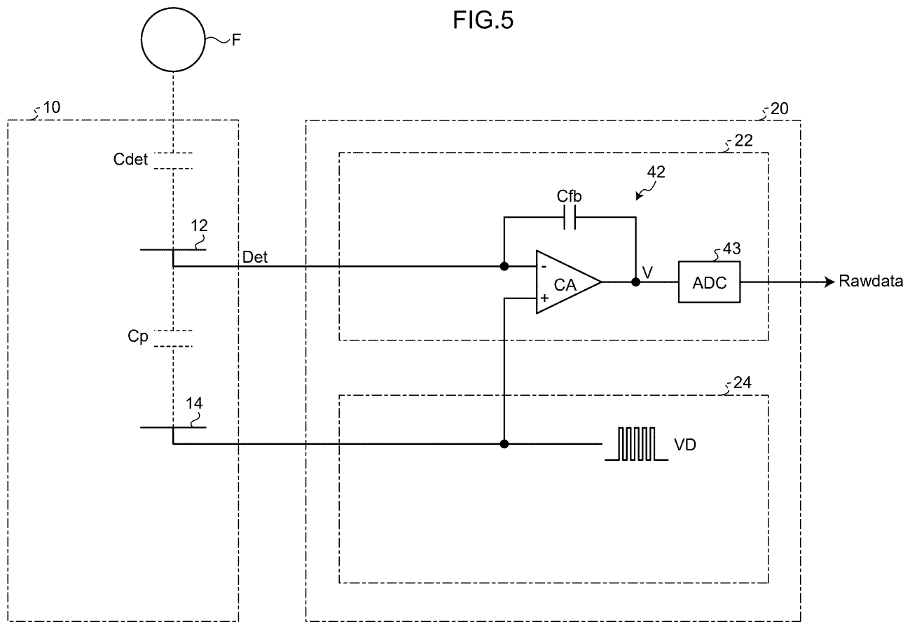

The following describes the baseline processing performed by the signal processor 44. FIG. 5 is a diagram of an example of the coupling configuration between the sensor and the detector of the detection device according to the embodiment.

As illustrated in FIG. 5, the signal detector 42 of the detection circuit 22 includes a differential amplifier circuit CA as a main component. The detection device 1 according to the present disclosure is a self-capacitance detection device that generates an electric field by the electrodes 12 to detect an object to be detected F.

The electrodes 12-1, 12-2, 12-3, and 12-4 of the first functional region PAA1, the second functional region PAA2, the third functional region PAA3, and the fourth functional region PAA4 are each coupled to an inverting input terminal of the differential amplifier circuit CA of the signal detector 42. In the following description, the electrodes 12-1, 12-2, 12-3, and 12-4 in the respective functional regions may be referred to collectively as the electrodes 12.

A non-inverting input terminal of the differential amplifier circuit CA is supplied with drive signals VD for detection from the power supply circuit 24. The drive signal VD is a square wave signal having a waveform in which a high potential and a low potential are repeated alternately in a predetermined cycle. A negative feedback capacitor Cfb is provided between the inverting input terminal and the output terminal of the differential amplifier circuit CA. The differential amplifier circuit CA functions as an integration circuit by the drive signals VD being supplied to the non-inverting input terminal.

The shield electrode 14 is supplied with the drive signals VD from the power supply circuit 24.

The detection value Rawdata acquired in a detection operation is expressed by the following Expression (1), where S(Cdet) is a component caused by capacitance Cdet generated between the object to be detected F and the electrode 12, and S(Cp) is a component caused by parasitic capacitance Cp.

$$Rawdata = S ( Cdet ) + S ( Cp ) \qquad ( 1 )$$

The signal processor 44 subtracts a baseline BL (=S(Cp)), which has been determined in advance, from the detection value Rawdata of each electrode 12 acquired in the normal detection operation, thereby removing the component (S(Cp)) caused by the parasitic capacitance Cp. The baseline BL is the detection value acquired when the object to be detected F is not present in the space where an object can be detected on the detection region AA.

In the present disclosure, the electrode 12-1 in the first functional region PAA1, the electrode 12-2 in the second functional region PAA2, the electrode 12-3 in the third functional region PAA3, and the electrode 12-4 in the fourth functional region PAA4 have different sizes, and the detection sensitivities of the respective electrodes are assumed to be different. For this reason, various processes, such as baseline processing and linear transformation, in the signal processor 44 are performed as different processes for the respective functional regions.

In the example illustrated in FIG. 3, the signal processor 44 includes a first signal processor 44-1, a second signal processor 44-2, a third signal processor 44-3, and a fourth signal processor 44-4. The first signal processor 44-1 performs signal processing corresponding to the first functional region PAA1. The second signal processor 44-2 performs signal processing corresponding to the second functional region PAA2. The third signal processor 44-3 performs signal processing corresponding to the third functional region PAA3. The fourth signal processor 44-4 performs signal processing corresponding to the fourth functional region PAA4.

The first signal processor 44-1 performs various processes, such as baseline processing and linear transformation, on a detection value Rawdata1 of each electrode 12-1 and outputs the processing result as a detection value S1 of the electrode 12-1.

The second signal processor 44-2 performs various processes, such as baseline processing and linear transformation, on a detection value Rawdata2 of each electrode 12-2 and outputs the processing result as a detection value S2 of the electrode 12-2.

The third signal processor 44-3 performs various processes, such as baseline processing and linear transformation, on a detection value Rawdata3 of each electrode 12-3 and outputs the processing result as a detection value S3 of the electrode 12-3.

The fourth signal processor 44-4 performs various processes, such as baseline processing and linear transformation, on a detection value Rawdata4 of each electrode 12-4 and outputs the processing result as a detection value S4 of the electrode 12-4.

The arithmetic processor 45 performs arithmetic processing corresponding to each functional region. In the example illustrated in FIG. 3, the arithmetic processor 45 includes a first arithmetic processor 45-1, a second arithmetic processor 45-2, a third arithmetic processor 45-3, and a fourth arithmetic processor 45-4. The first arithmetic processor 45-1 performs arithmetic processing corresponding to the first functional region PAA1. The second arithmetic processor 45-2 performs arithmetic processing corresponding to the second functional region PAA2. The third arithmetic processor 45-3 performs arithmetic processing corresponding to the third functional region PAA3. The fourth arithmetic processor 45-4 performs arithmetic processing corresponding to the fourth functional region PAA4.

The first arithmetic processor 45-1 acquires spatial coordinates R1 (=(Rx, Ry, Rz)) including the position Rx in the X-direction, the position Ry in the Y-direction, and the position Rz in the Z-direction of the object to be detected in the space on the first functional region PAA1 based on the detection values S1 of the electrodes 12-1 in the first functional region PAA1.

The second arithmetic processor 45-2 acquires planar coordinates R2 (=(Rx, Ry)) including the position Rx in the X-direction and the position Ry in the Y-direction of the object to be detected in the second functional region PAA2 based on the detection values S2 of the electrodes 12-2 in the second functional region PAA2.

The third arithmetic processor 45-3 acquires a position R3 (=Rx) in the X-direction of the object to be detected in the third functional region PAA3 based on the detection values S3 of the electrodes 12-3 in the third functional region PAA3.

The fourth arithmetic processor 45-4 acquires presence or absence R4 (=1 or 0) of the object to be detected in the fourth functional region PAA4 based on the detection value S4 of the electrode 12-4 in the fourth functional region PAA4. More specifically, the fourth arithmetic processor 45-4 compares the detection value S4 of the electrode 12-4 in the fourth functional region PAA4 with a threshold and acquires the result of the comparison (specifically, “1” if the detection value S4 is equal to or larger than the threshold and “0” if the detection value S4 is smaller than the threshold, for example) as the processing result R4.

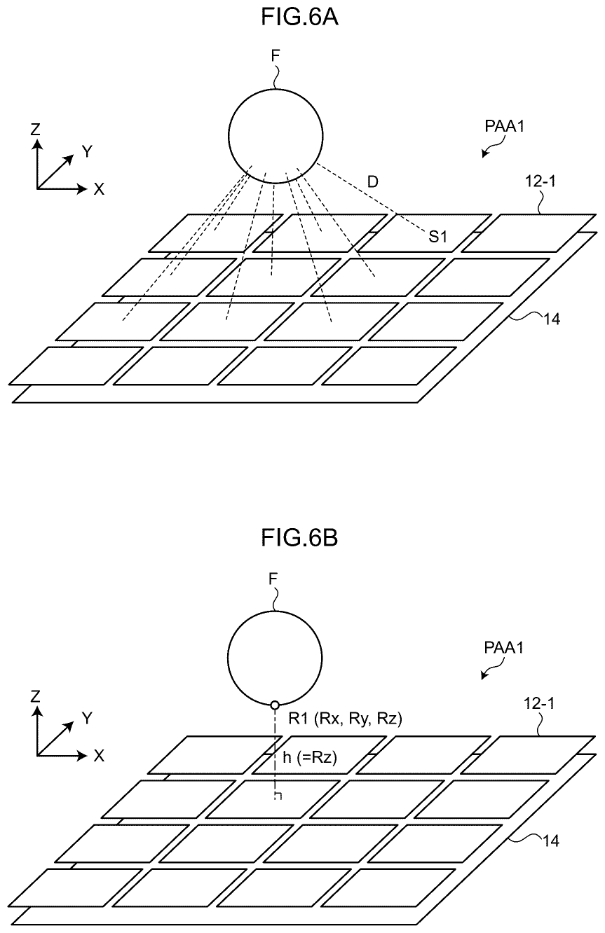

Next, a specific example of the detection operation performed by the detection device 1 is described. The following describes a specific example of the detection operation in the first functional region PAA1. FIG. 6A is a schematic of the relation between the position of the object to be detected in the space on the first functional region and the positions of the respective electrodes. FIG. 6B is a schematic of the spatial coordinates of the object to be detected in the space on the first functional region. FIGS. 6A and 6B illustrate an example of the operation performed when the object to be detected F is present in the space on the first functional region PAA1.

Capacitance corresponding to the distance D between the electrode 12-1 and the object to be detected F in the space on the first functional region PAA1 is generated at each electrode 12-1 in the first functional region PAA1, and the detection value Rawdata1 corresponding to the capacitance is acquired by the detection circuit 22. The detection value Rawdata1 acquired by the detection circuit 22 is subjected to various processes, such as baseline processing and linear transformation, by the first signal processor 44-1. As a result, the detection value S1 of each electrode 12-1 is generated.

The first arithmetic processor 45-1 calculates the spatial coordinates R1 (Rx, Ry, Rz) indicating the position of the object to be detected F in the space on the first functional region PAA1 illustrated in FIG. 6B based on the detection values S1 of the electrodes 12-1 generated by the first signal processor 44-1. The spatial coordinates R1 (Rx, Ry, Rz) include data Rx indicating the position in the X-direction on the first functional region PAA1, data Ry indicating the position in the Y-direction on the first functional region PAA1, and data Rz indicating the position in the Z-direction orthogonal to the X-Y plane.

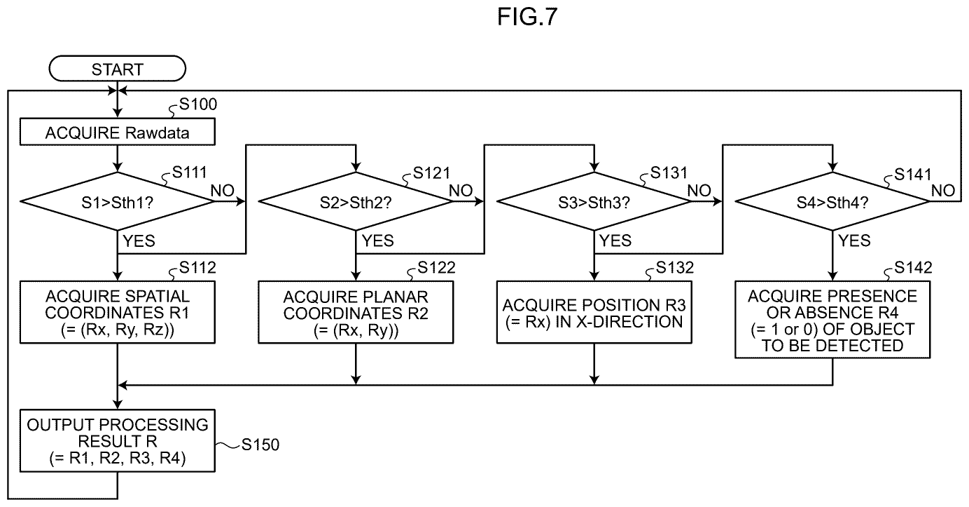

The following describes an example of specific operations performed by the processing circuit 23 in the detection device 1 according to the embodiment. FIG. 7 is a flowchart of an example of specific operations and processing performed by the processing circuit in the detection device according to the embodiment.

When the detection values Rawdata are acquired (Step S100), the processing selector 47 divides them into the detection value Rawdata1 of each electrode 12-1 in the first functional region PAA1, the detection value Rawdata2 of each electrode 12-2 in the second functional region PAA2, the detection value Rawdata3 of each electrode 12-3 in the third functional region PAA3, and the detection value Rawdata4 of the electrode 12-4 in the fourth functional region PAA4.

The signal processor 44 performs various processes, such as baseline processing and linear transformation, on the detection value Rawdata1 of each electrode 12-1 in the first functional region PAA1, the detection value Rawdata2 of each electrode 12-2 in the second functional region PAA2, the detection value Rawdata3 of each electrode 12-3 in the third functional region PAA3, and the detection value Rawdata4 of the electrode 12-4 in the fourth functional region PAA4. The signal processor 44 generates the detection value S1 of each electrode 12-1, the detection value S2 of each electrode 12-2, the detection value S3 of each electrode 12-3, and the detection value S4 of each electrode 12-4 and performs comparison arithmetic processing of comparing the detection values with respective thresholds.

Specifically, the first signal processor 44-1 determines whether the detection value S1 of each electrode 12-1 is equal to or smaller than a threshold Sth1 (Step S111). The second signal processor 44-2 determines whether the detection value S2 of each electrode 12-2 is equal to or smaller than a threshold Sth2 (Step S121). The third signal processor 44-3 determines whether the detection value S3 of each electrode 12-3 is equal to or smaller than a threshold Sth3 (Step S131). The fourth signal processor 44-4 determines whether the detection value S4 of each electrode 12-4 is equal to or smaller than a threshold Sth4 (Step S141).

The threshold Sth1 is a threshold for determining whether the object to be detected is present in the space where an object can be detected on the first functional region PAA1. If the detection value S1 of each electrode 12-1 is equal to or smaller than the threshold Sth1 (No at Step S111), the first signal processor 44-1 determines that the object to be detected is not present in the space where an object can be detected on the first functional region PAA1. If the detection value S1 of the electrode 12-1 is larger than the threshold Sth1 (Yes at Step S111), the first signal processor 44-1 determines that the object to be detected is present in the space where an object can be detected on the first functional region PAA1.

The threshold Sth2 is a threshold for determining whether the object to be detected is present in the space where an object can be detected on the second functional region PAA2. If the detection value S2 of each electrode 12-2 is equal to or smaller than the threshold Sth2 (No at Step S121), the second signal processor 44-2 determines that the object to be detected is not present in the space where an object can be detected on the second functional region PAA2. If the detection value S2 of the electrode 12-2 is larger than the threshold Sth2 (Yes at Step S121), the second signal processor 44-2 determines that the object to be detected is present in the space where an object can be detected on the second functional region PAA2.

The threshold Sth3 is a threshold for determining whether the object to be detected is present in the space where an object can be detected on the third functional region PAA3. If the detection value S3 of each electrode 12-3 is equal to or smaller than the threshold Sth3 (No at Step S131), the third signal processor 44-3 determines that the object to be detected is not present in the space where an object can be detected on the third functional region PAA3. If the detection value S3 of the electrode 12-3 is larger than the threshold Sth3 (Yes at Step S131), the third signal processor 44-3 determines that the object to be detected is present in the space where an object can be detected on the third functional region PAA3.

The threshold Sth4 is a threshold for determining whether the object to be detected is present in the space where an object can be detected on the fourth functional region PAA4. If the detection value S4 of each electrode 12-4 is equal to or smaller than the threshold Sth4 (No at Step S141), the fourth signal processor 44-4 determines that the object to be detected is not present in the space where an object can be detected on the fourth functional region PAA4. If the detection value S4 of the electrode 12-4 is larger than the threshold Sth4 (Yes at Step S141), the fourth signal processor 44 determines that the object to be detected is present in the space where an object can be detected on the fourth functional region PAA4.

If the detection value S1 of each electrode 12-1 is equal to or smaller than the threshold Sth1 (No at Step S111), the detection value S2 of each electrode 12-2 is equal to or smaller than the threshold Sth2 (No at Step S121), the detection value S3 of each electrode 12-3 is equal to or smaller than the threshold Sth3 (No at Step S131), and the detection value S4 of each electrode 12-4 is equal to or smaller than the threshold Sth4 (No at Step S141), the processing circuit 23 returns to Step S100, and repeatedly performs the processing starting at Step S100.

If the detection value S1 of the electrode 12-1 is larger than the threshold Sth1 (Yes at Step S111), that is, if it is determined that the object to be detected F is present in the space where an object can be detected on the first functional region PAA1, the first arithmetic processor 45-1 acquires the spatial coordinates R1 (=(Rx, Ry, Rz)) including the position Rx in the X-direction, the position Ry in the Y-direction, and the position Rz in the Z-direction of the object to be detected in the space on the first functional region PAAL based on the detection value S1 of each electrode 12-1 generated by the first signal processor 44-1 (Step S112).

If the detection value S2 of the electrode 12-2 is larger than the threshold Sth2 (Yes at Step S121), that is, if it is determined that the object to be detected F is present in the space where an object can be detected on the second functional region PAA2, the second arithmetic processor 45-2 acquires the planar coordinates R2 (=(Rx, Ry)) including the position Rx in the X-direction and the position Ry in the Y-direction of the object to be detected in the second functional region PAA2 based on the detection value S2 of each electrode 12-2 generated by the second signal processor 44-2 (Step S122).

If the detection value S3 of the electrode 12-3 is larger than the threshold Sth3 (Yes at Step S131), that is, if it is determined that the object to be detected F is present in the space where an object can be detected on the third functional region PAA3, the third arithmetic processor 45-3 acquires the position R3 (=Rx) in the X-direction of the object to be detected in the third functional region PAA3 based on the detection value S3 of each electrode 12-3 generated by the third signal processor 44-3 (Step S132).

If the detection value S4 of the electrode 12-4 is larger than the threshold Sth4 (Yes at Step S141), that is, if it is determined that the object to be detected F is present in the space where an object can be detected on the fourth functional region PAA4, the fourth arithmetic processor 45-4 acquires the presence or absence R4 (=1 or 0) of the object to be detected in the fourth functional region PAA4 based on the detection value S4 of each electrode 12-4 generated by the fourth signal processor 44-4 (Step S142).

The output processor 48 outputs the processing results (R1, R2, R3, R4) of the arithmetic processor 45 as one processing result R (=R1, R2, R3, R4) (Step S150).

The processing result R output from the processing circuit 23 is output from the interface circuit 25 to an external host device (not illustrated). The following describes a specific example of processing performed by the host device.

The host device detects an operation (e.g., gesture) corresponding to the movement of the object to be detected in the space on the first functional region PAA1 based on change in the spatial coordinates R1 (=(Rx, Ry, Rz)), for example.

The host device detects an operation (e.g., swiping, flicking, or a combined operation, such as drag-and-drop, pinch-in, and pinch-out) corresponding to the movement of the object to be detected in the second functional region PAA2 based on change in the planar coordinates R2 (=(Rx, Ry)).

The host device detects an operation (e.g., level control operation in home appliances and electronic apparatuses) corresponding to the movement of the object to be detected in the third functional region PAA3 based on change in the position Rx in the X-direction or the position Ry in the Y-direction, for example.

The host device detects an operation (e.g., toggle operation, such as switching ON/OFF of home appliances and electronic apparatuses) corresponding to the presence or absence of the object to be detected in the fourth functional region PAA4, for example.

In the configuration and processing of the detection device 1 according to the embodiment described above, the detection region AA provided on the single sensor substrate 11 is divided into a plurality of functional regions having different modes for detecting the object to be detected. The detection device 1 performs signal processing, such as baseline processing and linear transformation, on the detection value Rawdata of each electrode 12 and performs various arithmetic processes for the object to be detected for each functional region. The detection device 1 outputs the processing results as one processing result. With this configuration, the detection device 1 can efficiently implement different functions in a plurality of regions on a single touch device.

While exemplary embodiments according to the present disclosure have been described, the embodiments are not intended to limit the present disclosure. The contents disclosed in the embodiments are given by way of example only, and various modifications may be made without departing from the spirit of the present disclosure. Appropriate modifications made without departing from the spirit of the present disclosure naturally fall within the technical scope of the present disclosure.

What is claimed is:

1. A detection device comprising:
a detection region having a plurality of electrodes; and
a detector configured to detect an object to be detected in proximity to the detection region based on a detection value of each of the electrodes, wherein
the detection region is divided into a plurality of functional regions, and
the detector is configured such that the functional regions have different modes for detecting the object to be detected.

2. The detection device according to claim 1, wherein
the detection region includes, as the functional regions, at least one of:
a first functional region for acquiring spatial coordinates including a position in an X-direction, a position in a Y-direction orthogonal to the X-direction, and a position in a Z-direction orthogonal to the X-direction and the Y-direction of the object to be detected in a space on the functional region;
a second functional region for acquiring planar coordinates including a position in the X-direction and a position in the Y-direction of the object to be detected in the functional region;
a third functional region for acquiring a position in the X-direction or a position in the Y-direction of the object to be detected in the functional region; and
a fourth functional region for acquiring presence or absence of the object to be detected in the functional region.

3. The detection device according to claim 2, wherein
the detection region includes at least the first functional region as the functional regions,
the first functional region is a region where a plurality of electrodes are arranged in the X-direction and the Y-direction, and
the detector acquires the spatial coordinates of the object to be detected in the space on the first functional region based on a plurality of the detection values of the electrodes in the first functional region.

4. The detection device according to claim 2, wherein
the detection region includes at least the second functional region as the functional regions,
the second functional region is a region where a plurality of electrodes are arranged in the X-direction and the Y-direction, and
the detector acquires the planar coordinates of the object to be detected in the second functional region based on a plurality of the detection values of the electrodes in the second functional region.

5. The detection device according to claim 2, wherein
the detection region includes at least the third functional region as the functional regions,
the third functional region is a region where a plurality of electrodes are arranged in the X-direction or the Y-direction, and
the detector acquires the position in the X-direction or the position in the Y-direction of the object to be detected in the third functional region based on a plurality of the detection values of the electrodes in the third functional region.

6. The detection device according to claim 2, wherein
the detection region includes at least the fourth functional region as the functional regions,
the fourth functional region is a region provided with at least one electrode, and
the detector acquires the presence or absence of the object to be detected in the fourth functional region based on the detection value of the electrode in the fourth functional region.

7. The detection device according to claim 3, wherein the detector outputs processing results acquired in the functional regions as one processing result.

8. The detection device according to claim 4, wherein the detector outputs processing results acquired in the functional regions as one processing result.

9. The detection device according to claim 5, wherein the detector outputs processing results acquired in the functional regions as one processing result.

10. The detection device according to claim 6, wherein the detector outputs processing results acquired in the functional regions as one processing result.
